(19) United States
(12) Patent Application Publication
(10) Pub. No.: US 2026/0215217 A1
(43) Pub. Date: Jul. 23, 2026

(54) SUBSTRATE PROCESSING SYSTEM AND TEACHING METHOD

(71) Applicant: Tokyo Electron Limited, Tokyo (JP)

(72) Inventors: Kosuke KINOSHITA, Tokyo (JP); Takashi SUGIMOTO, Yamanashi (JP)

(21) Appl. No.: 19/442,569

(22) Filed: Jan. 7, 2026

(30) Foreign Application Priority Data
Jan. 21, 2025 (JP) 2025-008679

(51) Int. Cl. H10P 72/50; H10P 72/30

(52) U.S. Cl. CPC H10P 72/50; H10P 72/3311

(57) ABSTRACT

A substrate processing system includes a transfer module, a first transfer apparatus installed in the transfer module and having a plurality of end effectors configured to respectively hold a plurality of substrates, and a control device including a processor and a memory coupled to the processor, the control device configured to control an operation of the first transfer apparatus. The first transfer apparatus is configured to simultaneously transfer the plurality of substrates. The control device controls (A) calculating a center-to-center distance between the plurality of substrates when the plurality of substrates are respectively held by the plurality of end effectors, and (B) adjusting a position when the plurality of substrates are held by the plurality of end effectors based on the center-to-center distance between the plurality of substrates calculated in the (A) and a design value of the center-to-center distance between the plurality of substrates.

### CROSS-REFERENCE TO RELATED APPLICATIONS

This application claims priority to Japanese Patent Application No. 2025-008679, filed January 21, 2025, the entire content of which is incorporated herein by reference.

### BACKGROUND

### Technical Field

The present disclosure relates to a substrate processing system and a teaching method.

### Description of Related Art

Japanese Unexamined Patent Application Publication No. 2024-57943 (hereinafter “Patent Document 1”) discloses a substrate processing system (substrate transfer system) provided with a vacuum transfer apparatus for simultaneously transferring a plurality of substrates in a vacuum transfer chamber. In the case where there are variations in the distance between the centers of the plurality of substrates placed on respective stages in respective processing chambers, a control device of this substrate processing system can transfer each substrate to a position shifted within an allowable range.

### SUMMARY

According to one aspect of the present disclosure, a substrate processing system includes a transfer module, a first transfer apparatus installed in the transfer module and having a plurality of end effectors configured to respectively hold a plurality of substrates, and a control device including a processor and a memory coupled to the processor, the control device configured to control an operation of the first transfer apparatus. The first transfer apparatus is configured to simultaneously transfer the plurality of substrates. The control device controls (A) calculating a center-to-center distance between the plurality of substrates when the plurality of substrates are respectively held by the plurality of end effectors, and (B) adjusting a position when the plurality of substrates are held by the plurality of end effectors based on the center-to-center distance between the plurality of substrates calculated in the (A) and a design value of the center-to-center distance between the plurality of substrates.

### BRIEF DESCRIPTION OF THE DRAWINGS

FIG. 1 is a plan view schematically illustrating a configuration of a substrate processing system according to an embodiment;

FIG. 2 is a plan view schematically illustrating a configuration of an atmospheric transfer apparatus;

FIG. 3 is a plan view schematically illustrating a configuration of a vacuum transfer apparatus;

FIG. 4A is a diagram illustrating an example of transfer of a plurality of substrates by an end effector of a conventional vacuum transfer apparatus;

FIG. 4B is a diagram illustrating an example of placing substrates on respective movable stages;

FIG. 5 is a flowchart illustrating steps of a teaching method according to an embodiment;

FIG. 6 is a plan view illustrating an end effector according to the embodiment;

FIG. 7 is a flowchart illustrating a process flow in step S100 of the teaching method;

FIG. 8 is a diagram illustrating detection positions of a position detector in the process flow of FIG. 7;

FIG. 9 is a flowchart illustrating a process flow in step S200 of the teaching method;

FIG. 10A is a plan view illustrating a substrate held by the end effector;

FIG. 10B is a diagram illustrating detection positions of a position detector in a process flow of FIG. 9;

FIG. 11 is a flowchart illustrating a process flow in step S300 of the teaching method;

FIG. 12A is a plan view illustrating a substrate held at a center of each end effector;

FIG. 12B is a plan view illustrating a substrate held at each end effector based on each design value; and

FIG. 13 is a view illustrating a state in which each position-adjusted substrate is transferred to a respective stage of a processing module.

### DETAILED DESCRIPTION

The present disclosure provides a technique for accurately transferring a plurality of substrates to a target position when the substrates are simultaneously transferred.

Hereinafter, an embodiment of the present disclosure will be described with reference to the drawings. In each of the drawings, the same components are denoted by the same reference numerals, and redundant descriptions may be omitted.

### Substrate Processing System 100

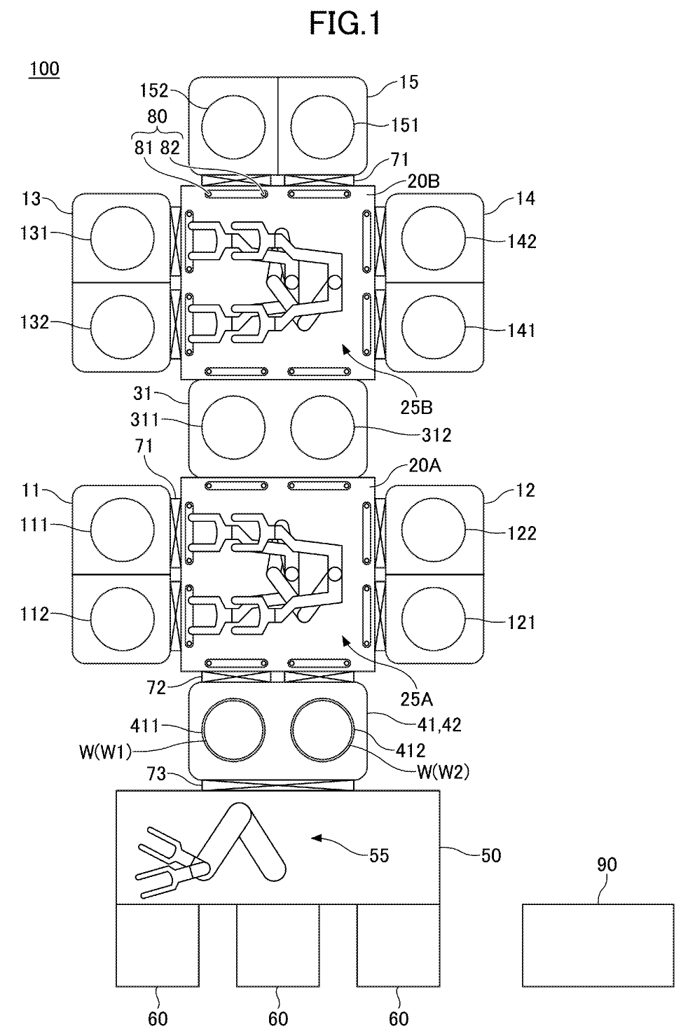

An example of a substrate processing system 100 according to an embodiment will be described with reference to FIG. 1. FIG. 1 is a plan view schematically illustrating the configuration of the substrate processing system 100 according to the embodiment.

The substrate processing system 100 is a system of a cluster structure (multi-chamber type) having a plurality of processing modules 11 through 15. In addition to the plurality of processing modules 11 through 15, the substrate processing system 100 includes vacuum transfer modules 20A and 20B, a pass module 31, load lock modules 41 and 42, an atmospheric transfer module 50, a load port 60, and a control device 90. FIG. 1 illustrates a state in which a substrate W is placed on each of the mounting platforms 411 and 412 of the load lock module 41. In the following description, a substrate placed on the mounting platform 411 of FIG. 1 is denoted by “W1”, and a substrate placed on the placing section 412 of FIG. 1 is denoted by “W2”.

The processing module 11 is provided with a processing container, and the inside of the processing container is provided with a plurality of (in this example, two) stages 111 and 112 on which two substrates W can be respectively placed. Similarly, the processing module 12 has two stages 121 and 122 on which two substrates W can be respectively placed. The processing module 13 has two stages 131 and 132 on which two substrates W can be respectively placed. The processing module 14 has two stages 141 and 142 on which two substrates W can be respectively placed. The processing module 15 has two stages 151 and 152 capable of placing two substrates W. The internal space of each of the processing modules 11 through 15 can be reduced to a vacuum atmosphere by a suction device (not illustrated) connected to each module. In the processing container of each of the processing modules 11 through 15, the two stages may be provided in a communicating internal space or in an internal space divided by a partition or the like. Each of the processing modules 11 through 15 performs substrate processing (for example, an etching process, a film formation process, a cleaning process, an ashing process, and the like) on each of substrates W1 and W2 respectively placed on the two stages under the control of the control device 90.

The stage 111 has a regular circular mounting surface having a diameter larger than the diameter of a substrate W in plan view. The mounting surface of the stage 111 has, for example, an annular edge protrusion on the outer periphery, and is therefore formed concave in cross-sectional view. The stage 111 may be a movable component provided with an operation mechanism for displacing the entire stage in the horizontal direction (X-Y axis direction). The same applies to the stages 112, 121, 122, 131, 132, 141, 142, 151, and 152.

The processing module 11 is connected to the vacuum transfer module 20A via a pair of gate valves 71. The gate valves 71 are provided at respective positions facing the stage 111 and the stage 112 in the processing container of the processing module 11. The processing module 11 and the vacuum transfer module 20A communicate by opening each of the gate valves 71. The pressure in the processing container of the processing module 11 can be reduced by closing each of the gate valves 71. The same applies to the processing module 12.

Similarly, the processing module 13 is connected to the vacuum transfer module 20B via a pair of gate valves 71. The gate valves 71 are provided at respective positions facing the stage 131 and the stage 132 in the processing container of the processing module 11. The processing module 13 and the vacuum transfer module 20B communicate by opening each of the gate valves 71. The pressure in the processing container of the processing module 13 can be reduced by closing each of the gate valves 71. The same applies to the processing modules 14 and 15.

The vacuum transfer module 20A is connected to the load lock modules 41 and 42 and the pass module 31, in addition to the processing modules 11 and 12. A pair of gate valves 72 is provided between the vacuum transfer module 20A and the load lock modules 41 and 42 to open and close therebetween. The vacuum transfer module 20B is connected to the pass module 31, in addition to the processing modules 13 through 15.

Each of the vacuum transfer modules 20A and 20B has a transfer container in which the pressure can be reduced to a vacuum atmosphere by a suction device (not illustrated). The vacuum transfer module 20A is provided with a vacuum transfer apparatus 25A for transferring substrates W. The vacuum transfer module 20B is provided with a vacuum transfer apparatus 25B for transferring substrates W. The vacuum transfer apparatuses 25A and 25B are configured to simultaneously transfer a plurality of substrates W (two substrates in FIG. 1).

The pass module 31 is a module for connecting the vacuum transfer module 20A and the vacuum transfer module 20B and letting a plurality of substrates W temporarily stand by. In the container of the pass module 31, two mounting platforms 311 and 312 on which a plurality of substrates W are placed respectively are provided. The pass module 31 is configured to be decompressible in a vacuum atmosphere together with the vacuum transfer modules 20A and 20B.

The vacuum transfer apparatus 25A moves in the vacuum transfer module 20A to load and unload substrates W into and from the processing modules 11 and 12, the pass module 31, and the load lock modules 41 and 42. The vacuum transfer apparatus 25B moves in the vacuum transfer module 20B to load and unload substrates W into and from the processing modules 13 through 15 and the pass module 31. The operation of the vacuum transfer apparatuses 25A and 25B and the opening and closing of the gate valves 71 and 72 are controlled by the control device 90.

The vacuum transfer module 20A is provided with position detectors 80 for detecting the positions of two substrates W transferred by the vacuum transfer apparatus 25A, at positions next to the processing module 11 in the transfer container. Each position detector 80 has, for example, two optical interrupters 81 and 82 for each transfer path of a substrate W. The optical interrupters 81 and 82 are optical sensors capable of detecting the edge of a detection target object. When two substrates W held by the vacuum transfer apparatus 25A are transferred from the vacuum transfer module 20A to the processing module 11, the optical interrupters 81 and 82 detect the outer edges of the substrates W. Thus, the positions of substrates W in the vacuum transfer apparatus 25A (the relative positions of substrates W with respect to the vacuum transfer apparatus 25A) can be recognized. The position detector 80 is communicatively connected to the control device 90, and transmits to the control device 90 detection information of substrates W detected when the substrates W are transferred.

Similarly, the vacuum transfer module 20A includes the position detectors 80 also at positions next to the processing module 12, positions next to the load lock modules 41 and 42, and positions next to the pass module 31. The vacuum transfer module 20B also includes the position detectors 80 at positions next to the processing module 13, positions next to the processing module 14, positions next to the processing module 15, and next positions next to the pass module 31.

The load lock modules 41 and 42 are provided between the vacuum transfer module 20A and the atmospheric transfer module 50, and are configured to switch between an atmospheric atmosphere and a vacuum atmosphere by a pressure controller (not illustrated). The load lock modules 41 and 42 are connected to the vacuum transfer module 20A via the gate valves 72, and to the atmospheric transfer module 50 via a door valve 73.

The load lock module 41 and the load lock module 42 are arranged so as to overlap each other vertically. In FIG. 1, the load lock module 42 is arranged below the load lock module 41. However, the arrangement of the load lock module 41 and the load lock module 42 is not limited to this, and these modules may be arranged side by side (in a horizontal direction).

The load lock module 41 has two mounting platforms 411 and 412 on which two substrates W can be respectively placed. Similarly, the load lock module 42 also has two mounting platforms (not illustrated) on which two substrates W can be respectively placed. The load lock modules 41 and 42 and the vacuum transfer module 20A communicate when the gate valves 72 are opened in a state of a vacuum atmosphere. The load lock modules 41 and 42 and the atmospheric transfer module 50 communicate when the door valve 73 is opened in a state of an atmospheric atmosphere. The switching between the vacuum atmosphere and the atmospheric atmosphere of the load lock modules 41 and 42 is performed by the control device 90 controlling the pressure controller.

The atmospheric transfer module 50 is provided with a transfer container having an internal space of an atmospheric atmosphere, and the inside of the atmospheric transfer module 50 is provided with an atmospheric transfer apparatus 55 for transferring substrates W. The atmospheric transfer apparatus 55 is configured to transfer substrates W one by one. The atmospheric transfer module 50 may be provided with, for example, an FFU (fan filter unit) for downflowing clean air to the internal space.

A plurality of load ports 60 are provided on one side surface of the atmospheric transfer module 50. A carrier containing a substrate W or an empty carrier is attached to each load port 60. A FOUP (front opening unified pod) may be used as the carrier, for example.

The atmospheric transfer apparatus 55 loads and unloads a substrate W between the load lock modules 41 and 42 and the atmospheric transfer module 50 in accordance with the opening and closing of the door valve 73. The atmospheric transfer apparatus 55 loads and unloads a substrate W between the atmospheric transfer module 50 and the carrier attached to the load port 60. The operation of the atmospheric transfer apparatus 55 and the opening and closing of the door valve 73 are controlled by the control device 90.

The control device 90 is a computer having a processor, a memory, an input/output interface, and a communication interface. The processor is a combination of one or more of a CPU (central processing unit), a GPU (graphics processing unit), an ASIC (application specific integrated circuit), an FPGA (field-programmable gate array), a circuit composed of a plurality of discrete semiconductors, and the like. The memory includes a main storage device composed of a semiconductor memory and the like, and an auxiliary storage device composed of a disk, a semiconductor memory (flash memory), and the like. The memory may be constituted by appropriately combining a volatile memory and a nonvolatile memory (for example, compact disc, digital versatile disc (DVD), hard disk, flash memory, etc.).

The memory stores a program for operating the substrate processing system 100 and a recipe such as process conditions for substrate processing. The processor controls each configuration of the substrate processing system 100 by reading and executing the program from the memory. In other words, the control device 90 is an electronic circuit having a CPU, a GPU, an ASIC, an FPGA, or the like, and performs various control operations described herein by executing instruction codes stored in the memory or by designing a circuit for a special application. The controller may be composed of a host computer or a plurality of client computers communicating information via a network.

### Atmospheric Transfer Apparatus 55

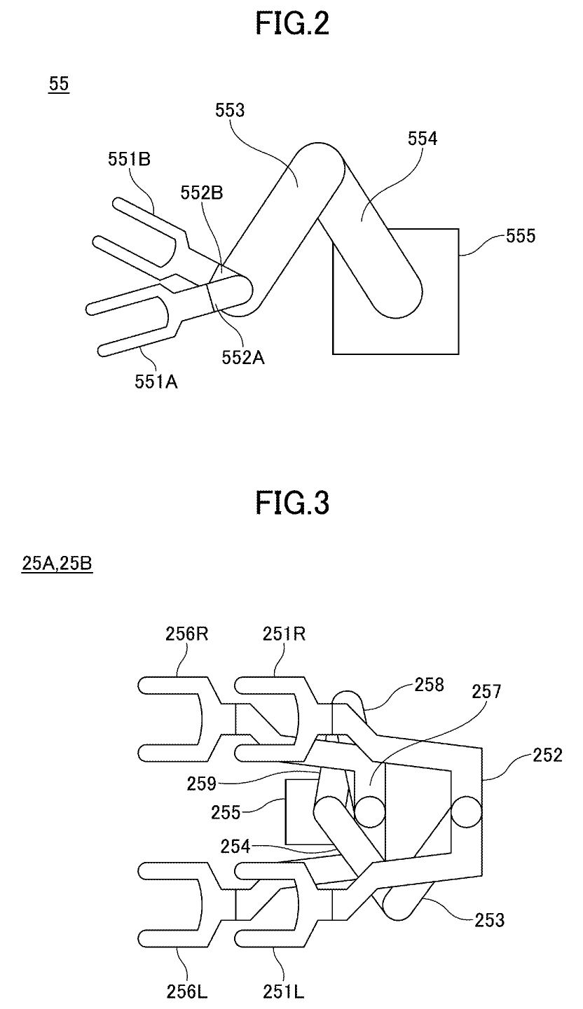

Next, the atmospheric transfer apparatus 55 will be described in detail with reference to FIG. 2. FIG. 2 is a plan view schematically illustrating the configuration of the atmospheric transfer apparatus 55. The atmospheric transfer apparatus 55 includes end effectors 551A and 551B, base portions 552A and 552B, arms 553 and 554, and a base 555.

The end effector (also referred to as a “pick” or “fork”) 551A is configured to hold a substrate W and fixed to one end of the base portion 552A. The other end of the base portion 552A is rotatably connected to one end of the arm 553. The end effector 551B is configured to hold a substrate W and fixed to one end of the base portion 552B. The other end of the base portion 552B is rotatably connected to one end of the arm 553. The end effector 551A and the end effector 551B are arranged at mutually different height positions. Thus, the atmospheric transfer apparatus 55 can have a configuration in which the end effectors 551A and 551B each holding a substrate W are stacked in two levels.

The arms 553 and 554 are, for example, scalar-type articulated arms. The other end of the arm 553 is rotatably connected to one end of the arm 554. The other end of the arm 554 is rotatably connected to the base 555. The control device 90 controls the position and orientation of the end effectors 551A and 551B by controlling the angle of each joint of the atmospheric transfer apparatus 55.

The base 555 has an elevating mechanism (not illustrated) for elevating and lowering the arm 554. The control device 90 can adjust the height of the end effectors 551A and 551B by controlling the elevating mechanism.

The atmospheric transfer apparatus 55 has a slide mechanism (not illustrated). The control device 90 controls the slide mechanism to move the configuration above the base 555 in parallel with the direction in which the plurality of load ports 60 (see FIG. 1) are arranged.

### Vacuum Transfer Apparatuses 25A and 25B

Next, the vacuum transfer apparatuses 25A and 25B will be further described with reference to FIG. 3. FIG. 3 is a plan view schematically illustrating the configuration of the vacuum transfer apparatuses 25A and 25B. Each of the vacuum transfer apparatuses 25A and 25B has end effectors 251R and 251L, a base 252, arms 253 and 254, a base 255, end effectors 256R and 256L, a base 257, and arms 258 and 259.

The end effectors 251R and 251L are configured to hold a substrate W and are respectively fixed to corresponding branches of the bifurcated base 252. In other words, the end effector 251R and the end effector 251L are configured to be integrally displaced without changing their relative positional relationship. The base 252 is rotatably connected to one end of the arm 253. The arms 253 and 254 are, for example, scalar-type articulated arms. The other end of the arm 253 is rotatably connected to one end of the arm 254. The other end of the arm 254 is rotatably connected to the base 555.

The end effectors 256R and 256L are configured to hold a substrate W and are respectively fixed to corresponding branches of the bifurcated base 257. In other words, the end effector 256R and the end effector 256L are configured to be integrally displaced without changing their relative positional relationship. The base 257 is rotatably connected to one end of the arm 258. The arms 258 and 259 are, for example, scalar-type articulated arms. The other end of the arm 258 is rotatably connected to one end of the arm 259. The other end of the arm 259 is rotatably connected to the base 555.

The end effectors 251R and 251L and the end effectors 256R and 256L are arranged at mutually different height positions. Thus, the vacuum transfer apparatuses 25A and 25B can have a configuration in which the end effectors 251R and 251L each holding a substrate W and the end effectors 256R and 256L each holding a substrate W are stacked in two levels. The base 255 has an elevating mechanism (not illustrated) for elevating and lowering the arms 254 and 259. The control device 90 can adjust the height positions of the end effectors 251R and 251L and the end effectors 256R and 256L by controlling the elevating mechanism.

### Transfer of Substrates W by Substrate Processing System 100

The above-described substrate processing system 100 transfers substrates W according to the following procedure under the control of the control device 90, for example, when the processing module 11 performs substrate processing on substrates W.

The control device 90 first controls the atmospheric transfer apparatus 55 to hold a substrate W1 in the carrier by one of the two end effectors 551A and 551B of the atmospheric transfer apparatus 55. The control device 90 also controls the atmospheric transfer apparatus 55 to hold a substrate W2 in the carrier by the other of the two end effectors 551A and 551B of the atmospheric transfer apparatus 55. The control device 90 then opens the door valve 73 of the load lock module 41.

The control device 90 controls the atmospheric transfer apparatus 55 to move one end effector 551A holding the substrate W1 to a previously taught substrate transfer position and to place the substrate W1 on the mounting platform 411 of the load lock module 41. The control device 90 also controls the atmospheric transfer apparatus 55 to move the other end effector 551B holding the substrate W2 to a previously taught substrate transfer position and to place the substrate W2 on the mounting platform 412 of the load lock module 41. When the atmospheric transfer apparatus 55 retreats from the load lock module 41, the control device 90 closes the door valve 73 and reduces the inside of the load lock module 41 to a vacuum atmosphere.

Next, the control device 90 opens the gate valves 72 of the load lock module 41. The control device 90 controls the vacuum transfer apparatus 25A to move the end effectors 251R and 251L to the substrate transfer positions of the load lock module 41, holds the substrate W1 by the end effector 251R, and holds the substrate W2 by the end effector 251L. The control device 90 controls the vacuum transfer apparatus 25A to unload the substrates W1 and W2 from the load lock module 41 and transfer them to the vacuum transfer module 20A. When the end effectors 251R and 251L retreat from the load lock module 41, the control device 90 closes the gate valves 72.

Next, the control device 90 opens the gate valves 71 of the processing module 11. The control device 90 controls the vacuum transfer apparatus 25A to load the end effector 251R holding the substrate W1 and the end effector 251L holding the substrate W2 into the processing module 11 and move them to the substrate transfer positions of the processing module 11, which is the target positions. Subsequently, the control device 90 causes the vacuum transfer apparatus 25A and a lifter (not illustrated) of the processing module 11 to work in conjunction so as to transfer the substrate W1 from the end effector 251R to the stage 111 and the substrate W2 from the end effector 251L to the stage 112. When the vacuum transfer apparatus 25A retreats from the processing module 11, the control device 90 closes the gate valves 71. Thus, the substrate processing system 100 can perform substrate processing on the substrates W1 and W2 supported by the stages 111 and 112. When the processing module 12 performs substrate processing on the substrates W1 and W2, the same procedure as described above can be adopted.

In the following, a case where a substrate W is subjected to substrate processing in the processing module 13 will be described. The processing until substrates W1 and W2 are unloaded from the load lock module 41 to the vacuum transfer module 20A is similar to the processing when substrates W1 and W2 are transferred to the processing module 11, and the description thereof is omitted.

The control device 90 controls the vacuum transfer apparatus 25A to load the end effector 251R holding a substrate W1 and the end effector 251L holding a substrate W2 into the pass module 31 and to move them to the substrate transfer positions of the respective mounting platforms 311 and 312 of the pass module 31. Then, the control device 90 controls the vacuum transfer apparatus 25A to place the substrate W1 on the mounting platform 312, place the substrate W2 on the mounting platform 311, and evacuate the vacuum transfer apparatus 25A from the pass module 31.

Next, the control device 90 controls the vacuum transfer apparatus 25B to move the end effectors 251R and 251L to the substrate transfer positions of the pass module 31, hold the substrate W1 by the end effector 251R, and hold the substrate W2 by the end effector 251L. Then, the control device 90 controls the vacuum transfer apparatus 25B to unload the substrates W1 and W2 from the pass module 31 to the vacuum transfer module 20B.

Next, the control device 90 opens the gate valves 71 of the processing module 13. The control device 90 controls the vacuum transfer apparatus 25B to move the end effector 251R holding the substrate W1 and the end effector 251L holding the substrate W2 to the substrate transfer positions of the processing module 13. Then, the control device 90 causes the vacuum transfer apparatus 25B and the lifter portion of the processing module 13 to work in conjunction so as to transfer the substrate W1 from the end effector 251R to the stage 131 and the substrate W2 from the end effector 251L to the stage 132. When the vacuum transfer apparatus 25B retreats from the processing module 13, the control device 90 closes the gate valves 71. Thus, the substrate processing system 100 can perform substrate processing on the substrates W1 and W2 loaded into the processing module 13. When the substrates W1 and W2 are subjected to substrate processing in the processing module 14 and when the substrates W1 and W2 are subjected to substrate processing in the processing module 15, the same procedure as described above can be adopted.

Furthermore, by controlling the vacuum transfer apparatuses 25A and 25B, the atmospheric transfer apparatus 55, the gate valves 71 and 72, and the door valve 73, the control device 90 can accommodate the substrates W1 and W2 subjected to substrate processing in the processing modules 11 through 15 in the carrier.

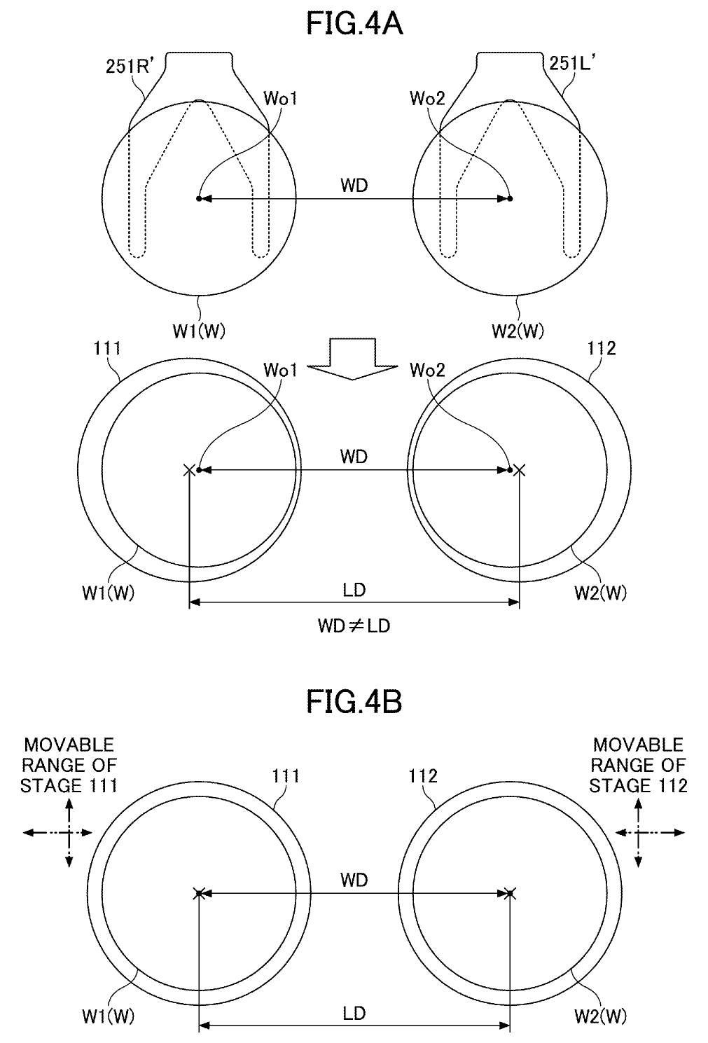

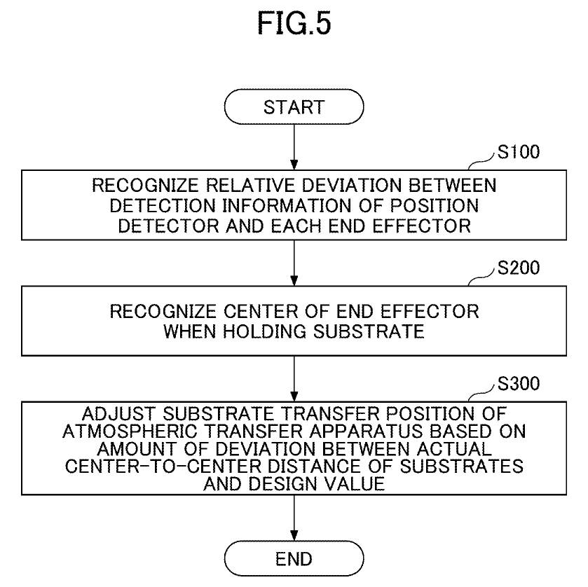

FIG. 4A is a diagram illustrating an example of transfer of a plurality of substrates W by the end effectors 251R′ and 251L′ of a conventional vacuum transfer apparatus. FIG. 4B is a diagram illustrating an example in which a substrate W is placed on each of the movable stages 111 and 112. Basically, the conventional vacuum transfer apparatus holds substrates W in such a manner that the center of the end effector 251R′ coincides with the center Wo1 of a substrate W1 and the center of the end effector 251L′ coincides with the center Wo2 of a substrate W2, as illustrated in FIG. 4A.

In the conventional vacuum transfer apparatus, a substrate transfer position is taught with reference to a substrate W placed at the center of each of the end effectors 251R′ and 251L′ by a person using a jig. Therefore, when a substrate transfer position is taught in this conventional vacuum transfer apparatus, an error occurs between a design value of the center-to-center distance WD, which is the distance between the center Wo1 of the substrate W1 and the center Wo2 of the substrate W2, and the actual center-to-center distance. In addition, the center-to-center distance between the substrates W1 and W2 respectively placed at the conventional end effectors 251R′ and 251L′ includes an assembling error and a processing error of the vacuum transfer apparatus.

In the vacuum transfer apparatus that has been taught in a conventional manner as described above, for example, when substrates W1 and W2 are transferred and respectively placed on the stages 111 and 112 of the processing module 11, the positions of the substrates W1 and W2 are shifted due to the deviation of the center-to-center distance WD from the design value. The design value herein is a predetermined center-to-center distance LD between the stages 111 and 112. For example, as illustrated in the diagram of FIG. 4A, the conventional vacuum transfer apparatus transfers the substrates so that the center Wo1 of the substrate W1 is shifted inward with respect to the center of the stage 111 and the center Wo2 of the substrate W2 is shifted inward with respect to the center of the stage 112. Due to this displacement, the substrates W1 and W2 are placed with a reduced clearance from the edge protrusions of the stages 111 and 112. In some cases, the substrates contact or ride over the edge protrusions.

As illustrated in FIG. 4B, in the case where the stages 111 and 112 of the respective processing modules 11 are movable, the substrates W can be respectively placed at the center of the stages 111 and 112 by moving the stages 111 and 112 based on the detection information of the position detectors 80. However, in this case, since the stages 111 and 112 are moved first, the movable ranges of the stages 111 and 112 become uneven, and the substrates W may not be disposed at an appropriate position during substrate processing.

In other words, in the case where the substrates W1 and W2 are simultaneously transferred, it is preferable to hold the substrates W1 and W2 by shifting them from the center of the respective end effectors 251R′ and 251L′ in accordance with the design values of the vacuum transfer apparatus and the stages 111 and 112. Therefore, in the substrate processing system 100 according to the embodiment, when teaching the substrate transfer positions to the vacuum transfer apparatuses 25A and 25B, the substrates W are respectively held by the end effectors 251R and 251L in accordance with the design values.

### Teaching Method

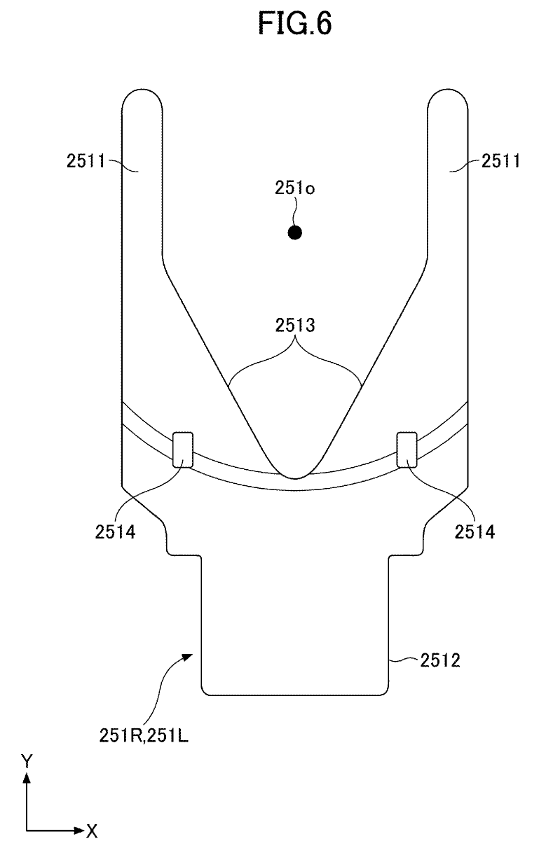

Hereinafter, a method of teaching the vacuum transfer apparatuses 25A and 25B of the substrate processing system 100 according to the embodiment, and the end effectors 251R and 251L used in this teaching method, will be described with reference to FIGS. 5 and 6. FIG. 5 is a flowchart illustrating steps of the teaching method according to the embodiment. FIG. 6 is a plan view illustrating the end effectors 251R and 251L according to the embodiment.

In the teaching method, the control device 90 illustrated in FIG. 1 controls each component of the substrate processing system 100 and sequentially performs steps S100, S200, and S300 illustrated in FIG. 5. Hereinafter, the method of teaching the vacuum transfer apparatus 25A for loading and unloading substrates W into and from the load lock module 41 will be described. It should be noted that adjusting the holding positions of substrates W in the vacuum transfer apparatus 25A allows the vacuum transfer apparatus 25B to hold the substrates W at the same center-to-center distance WD as in the vacuum transfer apparatus 25A. However, the following teaching method may be performed for the vacuum transfer apparatus 25B in the transfer of substrates W placed on the mounting platforms 311 and 312 of the pass module 31.

In step S100, the control device 90 recognizes a relative deviation between detection information of the position detectors 80 installed at the positions next to the load lock module 41 and the end effectors 251R and 251L of the vacuum transfer apparatus 25A. In other words, the substrate processing system 100 uses the position detectors 80 to recognize the current coordinates of the end effectors 251R and 251L or a substrate W. However, the position detectors 80 may cause a machine difference or a detection error of the device itself or an assembly error with respect to the vacuum transfer module 20A. Also, as described above, the vacuum transfer apparatus 25A itself may cause an assembly error or a processing error. Therefore, in the teaching method, a relative deviation between the position detectors 80 installed in the vacuum transfer module 20A and the end effectors 251R and 251L is obtained, and those errors are incorporated into the teaching in advance.

In order to obtain a relative deviation between the position detectors 80 and the end effectors 251R and 251L, the end effectors 251R and 251L have the structure illustrated in FIG. 6. Specifically, the end effectors 251R and 251L include a pair of fingers 2511 for supporting a substrate W, and a connection base portion 2512 for connecting the proximal ends of the pair of fingers 2511. The pair of fingers 2511 and the connection base portion 2512 are integrally formed of the same flat plate material.

The pair of fingers 2511 project substantially in parallel from the connection base portion 2512 toward the distal end direction. The upper surface of each finger 2511 forms a flat support surface for supporting a substrate W. Each of the end effectors 251R and 251L may be provided with three or more pads on the finger 2511 and the connection base portion 2512, and each pad may support the substrate W. Each of the end effectors 251R and 251L may be provided with a mechanism for performing vacuum attraction, electrostatic attraction, or mechanical locking to a supported substrate W.

The space between the fingers 2511 is defined as a substantially V-shaped (or substantially U-shaped) open space. The space between the fingers 2511 allows a pin of a lifter provided on a stage or the like to move forward or backward. Each finger 2511 has an inside edge 2513 defining the space between the fingers 2511. The inside edge 2513 extends parallel to the extending direction of the finger 2511 at the distal end side of each finger 2511, and is inclined inward in the width direction toward the proximal end direction (the depth direction of the space) of each finger 2511.

The connection base portion 2512 supports each finger 2511 at its distal end, and its proximal end is connected to the base 252 (see FIG. 3). The end effectors 251R and 251L support a circular substrate W so that the outer edge of a substrate W is positioned at the boundary between the connection base portion 2512 and the respective fingers 2511. The boundary may be provided with a step or the like for guiding the outer edge of a substrate W.

Rectangular through-holes 2514 are provided at the boundary. The longitudinal direction of each through-hole 2514 is parallel to the extending direction of the fingers 2511, and the shorter direction is parallel to the width direction of the fingers 2511. A pair of the through-holes 2514 is provided in accordance with the pair of fingers 2511. When a virtual line parallel to the longitudinal direction of each through-hole 2514 is extended toward the distal end direction of the end effectors 251R and 251L, the virtual line overlaps the inclined portion of the inner edge 2513. In other words, each through-hole 2514 is provided at a position aligned with the inclined portion of the inner edge 2513 in the advancing and retreating direction of the end effectors 251R and 251L.

In the teaching method, a relative positional deviation between the detection information of the position detectors 80 and the end effectors 251R and 251L of the vacuum transfer apparatus 25A is recognized by using the inner edge 2513 of the end effectors 251R and 251L and the through-holes 2514. This method will be described later in detail.

Returning to FIG. 5, in the next step S200, the control device 90 recognizes the centers 251o (see FIG. 6) of the end effectors 251R and 251L when the substrates W are held by the vacuum transfer apparatus 25A. The vacuum transfer apparatus 25A according to the embodiment can hold the substrates W with the centers Wo shifted from the centers 251o of the end effectors 251R and 251L. However, the vacuum transfer apparatus 25A cannot hold the substrates W with the centers Wo shifted unless the vacuum transfer apparatus 25A recognizes the centers 251o of the end effectors 251R and 251L. Therefore, in the teaching method, the centers 251o of the end effectors 251R and 251L are recognized in step S200. The through-holes 2514 of the end effectors 251R and 251L are also used in step S200. This method will be described later in detail.

Then, in the final step S300, the control device 90 adjusts the substrate transfer positions when the atmospheric transfer apparatus 55 transfers the substrates W, based on the difference between the actual center-to-center distance WD between the substrates W and the design value of the center-to-center distance. At this time, the control device 90 adjusts the substrate transfer positions of the atmospheric transfer apparatus 55 so that the relative position of the center Wo of each substrate W and the center of each of the end effectors 251R and 251L are equally deviated from each other. This method will also be described later in detail.

By going through the above-described steps S100, S200, and S300, the vacuum transfer apparatuses 25A and 25B can adjust the holding position of each of the end effectors 251R and 251L when simultaneously transferring the substrates W from the mounting platforms 411 and 412 of the load lock modules 41 and 42. As a result, the substrate processing system 100 can transfer the substrates W by the vacuum transfer apparatuses 25A and 25B so that the center of each substrate W coincides with the center of the corresponding respective stage of the processing modules 11 through 15.

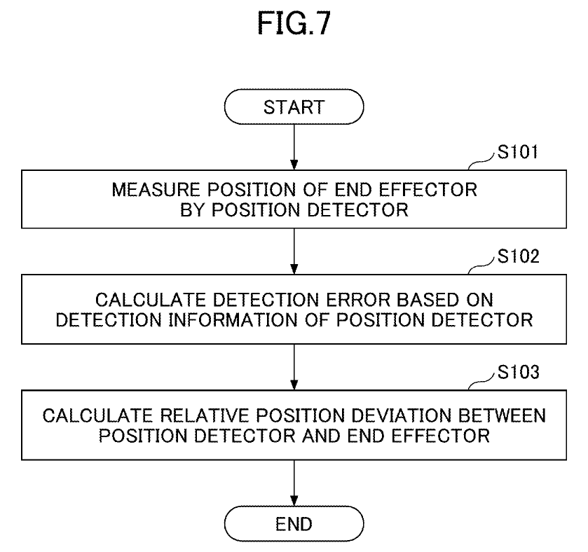

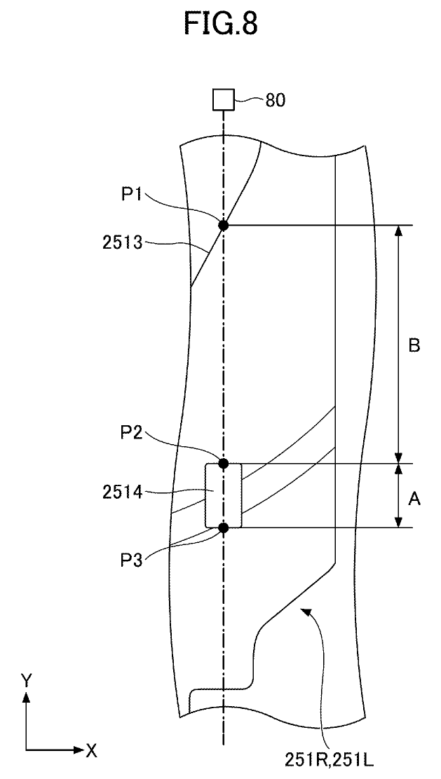

Hereinafter, specific processing in each of steps S100, S200, and S300 will be described with reference to the respective drawings. FIG. 7 is a flowchart illustrating the process flow in step S100 of the teaching method. FIG. 8 is a diagram illustrating detection positions of the position detector 80 in the process flow of FIG. 7.

The control device 90 controls each component of the substrate processing system 100 to perform steps S101 through S103 in step S100. Steps S101 to S103 are performed in a state where the substrates W are not held by the respective end effectors 251R and 251L of the vacuum transfer apparatus 25A.

Specifically, in step S101, the end effectors 251R and 251L of the vacuum transfer apparatus 25A are made to enter the load lock module 41, and the positions of the end effectors 251R and 251L are respectively detected by the position detectors 80 installed at the positions next to the load lock module 41. As described above, the position detector 80 detects two positions on the outer edge of the substrate W by the pair of optical interrupters 81 and 82 (see also FIG. 1). The optical interrupters 81 and 82 are provided separated from each other by a distance that is narrower than the distance between the fingers 2511 of each of the end effectors 251R and 251L.

The control device 90 controls the vacuum transfer apparatus 25A of the vacuum transfer apparatus 25A based on the coordinate information of the load lock module 41 obtained in advance, and expands and contracts the base 252 at a position opposed to the position detector 80 (optical interrupters 81 and 82). Therefore, as illustrated in FIG. 8, the end effectors 251R and 251L advance in parallel with the extending direction of the fingers 2511, and at this time, the position detector 80 detects the edges of each of the end effectors 251R and 251L inside the fingers 2511. In other words, positions P1, P2, and P3 illustrated in FIG. 8 are detected by the position detector 80.

Position P1 is the position of the inner edge 2513 of the finger 2511. Position P2 is the position of the inner edge on the distal end side of the through-hole 2514. Position P3 is the position of the inner edge on the proximal end side of the through-hole 2514. The control device 90 measures the coordinates corresponding to the movement of the end effectors 251R and 251 by various sensors of the vacuum transfer apparatus 25A, and can recognize the coordinates of positions P1, P2, and P3 based on the detection timing at positions P1, P2, and P3 and the measured coordinates.

Returning to FIG. 7, in step S102, the control device 90 calculates the detection error (deviation amount s) of the position detector 80 based on the detection information of the position detector 80. Specifically, by subtracting the coordinates of position P2 from the coordinates of position P3, a distance A (see FIG. 8), which is the interval between the inner edges of the through-hole 2514, is first calculated. This distance A becomes a constant value (absolute value) regardless of the positional relationship of the end effectors 251R and 251L. Herein, in the position detector 80, the measured length of the distance A, which should ideally be constant, varies depending on the threshold value used to determine light interruption and light transmission. Furthermore, the measured length of the distance A varies depending on the detection sensitivity of the optical interrupters 81 and 82, the spread of the optical axis, and other similar factors. Therefore, in the teaching method, the difference between the distance A and the design value (in other words, the actual longitudinal dimension of the through-hole 2514) is calculated to obtain the deviation amount s, and the subsequent calculated distances are corrected for the deviation amount s.

In step S103, the control device 90 calculates the relative positional deviation between the position detector 80 and each of the end effectors 251R and 251L. Specifically, a distance B (see FIG. 8) is calculated by subtracting the coordinates of position P1 from the coordinates of position P2. When calculating the distance B, the previously calculated deviation amount s is considered (corrected) to obtain the distance B that coincides with the actual dimension. Herein, the coordinates of position P1 change due to the deviation in the X-axis direction because the inner edge 2513 is inclined. Therefore, the distance B also changes. By comparing the distance B with a predetermined design value, the control device 90 can obtain the deviation amount between each of the end effectors 251R and 251L and the position detector 80 in the X-axis direction (i.e., a correction amount a).

By performing the above-described steps S101 through S103, the control device 90 can recognize the relative deviation between the detection information of the position detector 80 and the respective end effectors 251R and 251L of the vacuum transfer apparatus 25A (i.e., a deviation amount s or a correction amount a in the X-axis direction). In other words, it is possible to obtain correction means for each of the end effectors 251R and 251L that can eliminate an assembling error and a machining error of the position detector 80 or the vacuum transfer apparatus 25A.

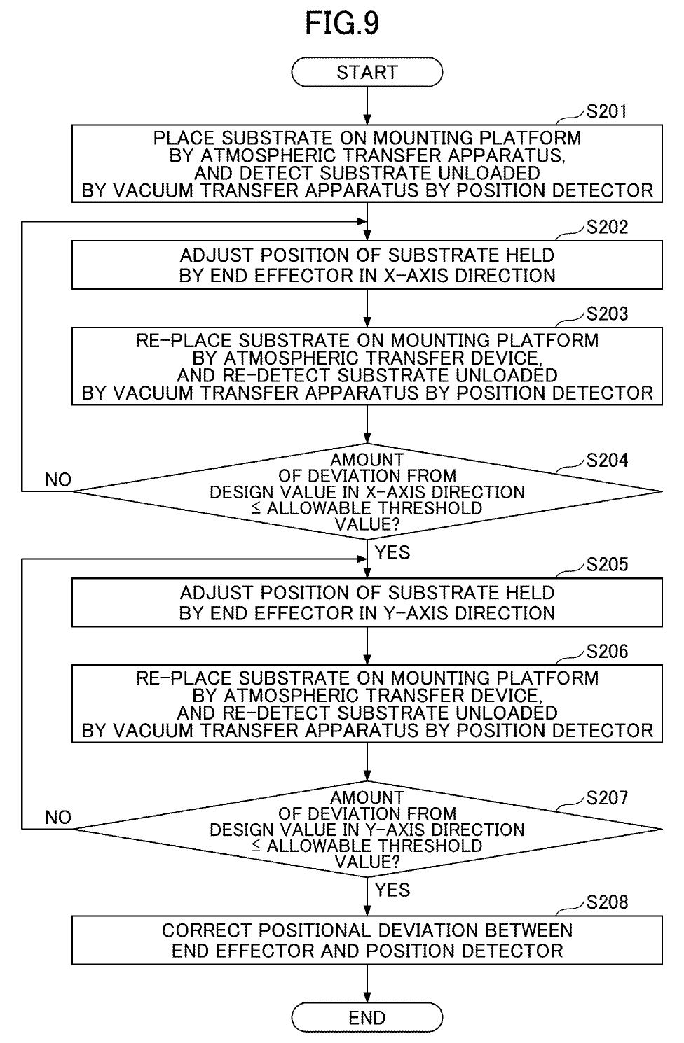

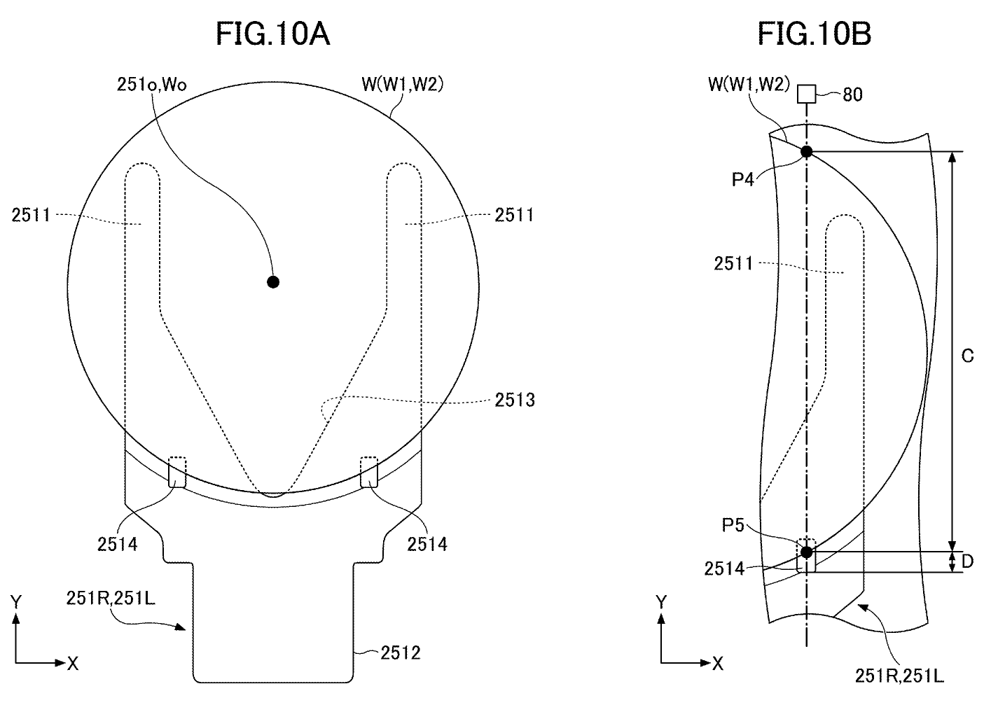

FIG. 9 is a flowchart illustrating the process flow in step S200 of the teaching method. FIG. 10A is a plan view illustrating a state in which the substrate W is held by the end effector 251R or 251L. FIG. 10B is a view illustrating detection positions of the position detector 80 in the process flow of FIG. 9. The control device 90 starts step S200 after step S100. In step S200, the control device 90 performs steps S201 to S208 of FIG. 9 by controlling each component of the substrate processing system 100. Steps S201 through S208 are performed in a state where the substrates W are held by the end effectors 251R and 251L of the vacuum transfer apparatus 25A.

More specifically, in step S201, the atmospheric transfer apparatus 55 transfers the substrates W, and places the substrates W1 and W2 on the mounting platforms 411 and 412 of the load lock module 41. At this time, the atmospheric transfer apparatus 55 places the substrates W on the mounting platforms 411 and 412 based on the substrate transfer positions of the atmospheric transfer apparatus 55 that are set in advance. Then, after unloading the substrates W1 and W2 from the load lock module 41, the vacuum transfer apparatus 25A makes the end effectors 251R and 251L enter the load lock module 41 to detect the substrates W1 and W2 by the respective position detectors 80 installed at the positions next to the load lock module 41. The detection of the substrates W1 and W2 may be performed when the vacuum transfer apparatus 25A unloads the substrates W1 and W2 from the load lock module 41.

As illustrated in FIG. 10A, the end effectors 251R and 251L position the outer edges of the substrates W outside the fingers 2511 when holding the substrates W. The end effectors 251R and 251L hold the substrates W in such a manner that the outer edge of each of the substrates W exactly overlaps the through-holes 2514. In this state, the vacuum transfer apparatus 25A advances the end effectors 251R and 251L, and the position detector 80 detects the outer edge of each of the substrates W. In other words, the position detector 80 detects positions P4 and P5 illustrated in FIG. 10B.

Position P4 is the position of the outer edge on the distal end side of the substrate W. Position P5 is the position of the outer edge on the proximal end side of the substrate W overlapping the through-hole 2514. The control device 90 measures the coordinates corresponding to the movement of the end effectors 251R and 251 by various sensors of the vacuum transfer apparatus 25A, and can recognize the coordinates of positions P4 and P5 based on the detection timing at positions P4 and P5 and the measured coordinates.

Returning to FIG. 9, in step S202, the control device 90 adjusts the positions of the substrates W1 and W2 on the respective end effectors 251R and 251L in the X-axis direction. More specifically, the control device 90 calculates a distance C (see FIG. 10B) by subtracting the coordinates of position P4 from the coordinates of position P5 based on the detection information of the position detector 80. When calculating the distance C, the deviation amount s calculated in step S102 is taken into consideration (corrected) to obtain the distance C that coincides with the actual size. Then, the control device 90 compares the calculated distance C with the design value (the distance C when the substrate W is held at the center) to calculate a difference, and changes the positions of the mounting platforms 411 and 412 in the X-axis direction that have been taught by the atmospheric transfer apparatus 55 so that the difference from the design value becomes zero.

In step S203, the control device 90 transfers the substrates W1 and W2 of the vacuum transfer apparatus 25A to the atmospheric transfer apparatus 55 via the load lock module 41, and respectively re-mounts the substrates W1 and W2 to the mounting platforms 411 and 412 by the atmospheric transfer apparatus 55 based on the changed taught positions. Then, after unloading the substrates W1 and W2 from the load lock module 41, the vacuum transfer apparatus 25A makes the end effectors 251R and 251L enter the load lock module 41, and re-detects the substrates W1 and W2 by the respective position detectors 80 installed at the positions next to the load lock module 41.

In step S204, the control device 90 uses the detection information of the re-detection by the position detectors 80 to determine whether or not the deviation amount (difference) from the design value is equal to or less than an allowable threshold value, for the substrates W1 and W2 in the X-axis direction held by the end effectors 251R and 251L. The allowable threshold value may be set in consideration of the transfer accuracy of the substrates W, and is set to, for example, 0.5 mm or less. If the deviation amount exceeds the allowable threshold value (No in step S204), the process returns to step S202, and the same process flow is repeated. On the other hand, if the deviation amount is equal to or less than the allowable threshold value (Yes in step S204), it can be considered that there is no positional deviation in the X-axis direction of the substrates W1 and W2 in the end effectors 251R and 251L. In this case, the process proceeds to step S205.

In step S205, the control device 90 adjusts the positions in the Y-axis direction of the substrates W1 and W2 held by the end effectors 251R and 251L. In other words, in the embodiment, the adjustment of the substrates W in the X-axis direction and the adjustment of the substrates W in the Y-axis direction are performed separately. More specifically, the control device 90 calculates a distance D (see FIG. 10B) by subtracting the coordinates of position P5 from the coordinates of position P3 based on the detection information of the position detector 80 acquired in step S203. When calculating the distance D, the deviation amount s calculated in step S102 is considered (corrected) to obtain the distance D that coincides with the actual size. For position P3, the coordinates detected in step S101 may be used, or they may be detected again in step S203.

Here, since the taught positions of the substrates W1 and W2 held by the end effectors 251R and 251L in the X-axis direction have already been adjusted, the substrates W1 and W2 are placed with a deviation only in the Y-axis direction. In other words, since the substrates W1 and W2 move back and forth relative to the through-holes 2514, the distance D in the Y-axis direction changes. Therefore, the control device 90 compares the calculated distance D with the design value (the distance D when the substrate W is held at the center) to calculate a difference, and changes the taught positions of the mounting platforms 411 and 412 in the Y-axis direction by the atmospheric transfer apparatus 55 so that the difference from the design value becomes zero.

In step S206, the control device 90 transfers the substrates W1 and W2 of the vacuum transfer apparatus 25A to the atmospheric transfer apparatus 55 in the load lock module 41, and re-places the substrates W1 and W2 on the mounting platforms 411 and 412 by the atmospheric transfer apparatus 55 based on the changed taught positions. Then, after unloading the substrates W1 and W2 from the load lock module 41, the vacuum transfer apparatus 25A makes the end effectors 251R and 251L enter the load lock module 41, and re-detects the substrates W1 and W2 by the respective position detectors 80 installed at the positions next to the load lock module 41.

In step S207, the control device 90 uses the detection information of the re-detection by the position detector 80 to determine whether or not the deviation amount (difference) of the respective substrates W1 and W2 in the Y-axis direction held by the respective end effectors 251R and 251L is equal to or less than an allowable threshold value. This allowable threshold value may be the same as or different from the allowable threshold value in the X-axis direction. If the deviation amount exceeds the allowable threshold value (No in step S207), the process returns to step S205 and the same process flow is repeated. On the other hand, if the deviation amount is equal to or less than the allowable threshold value (Yes in step S207), it can be considered that there is no deviation in the Y-axis direction of the respective substrates W1 and W2 in the respective end effectors 251R and 251L. In this case, the process proceeds to step S208.

In step S208, the control device 90 corrects the positional deviation between the respective end effectors 251R and 251L and the position detectors 80. More specifically, the taught positions in the X-axis direction at which the atmospheric transfer apparatus 55 places the substrates W1 and W2 on the respective mounting platforms 411 and 412 of the load lock module 41 are adjusted (corrected) by using the deviation amount in the X-axis direction (i.e., the correction amount a) calculated in step S103. Thus, the control device 90 can recognize the center 251o of each of the end effectors 251R and 251L including an assembling error and a processing error of the position detectors 80 or the vacuum transfer apparatus 25A.

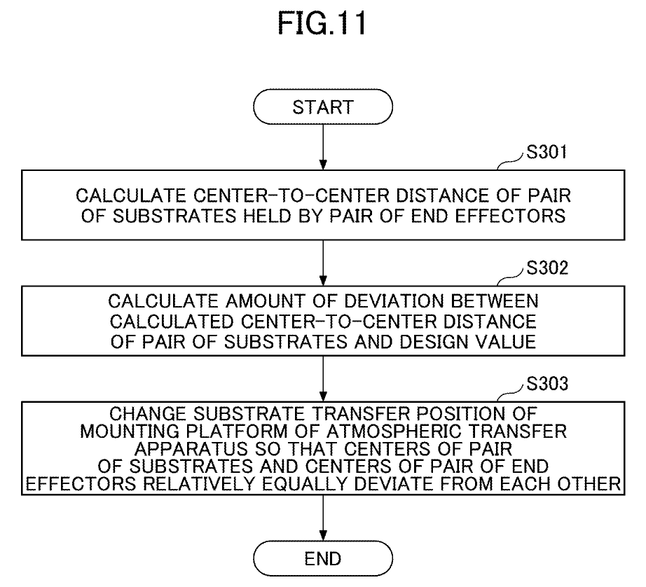

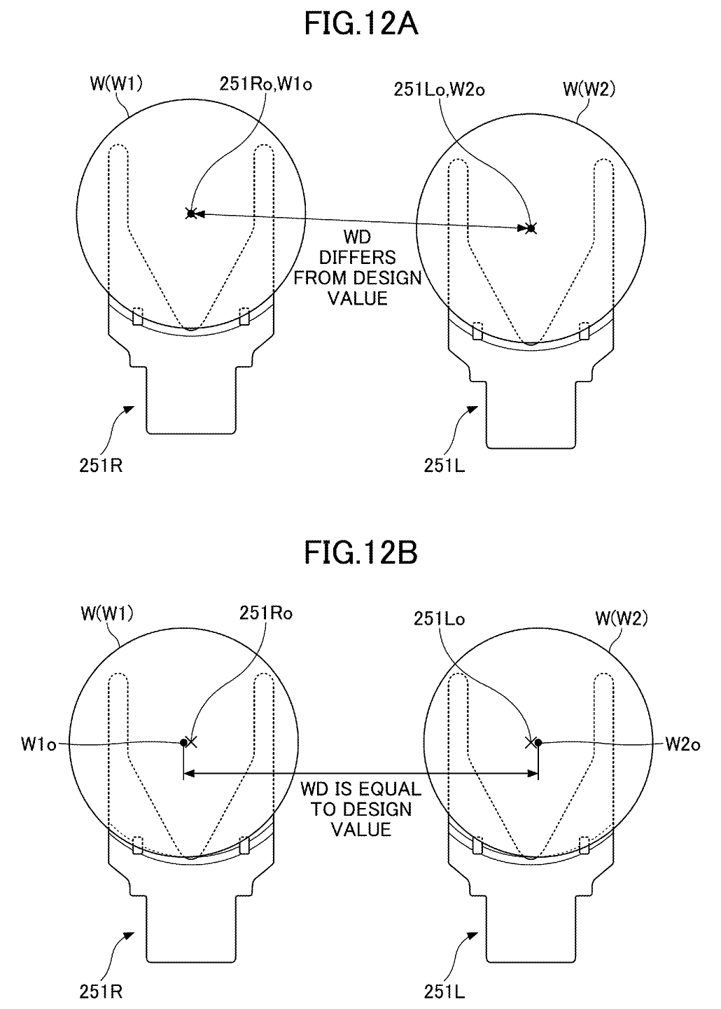

FIG. 11 is a flowchart illustrating the process flow in step S300 of the teaching method. FIG. 12A is a plan view illustrating a state in which the substrates W are held at the center of the respective end effectors 251R and 251L. FIG. 12B is a plan view illustrating a state in which the substrates W are held at the respective end effectors 251R and 251L based on the design value. The control device 90 starts step S300 after step S200. In step S300, the control device 90 performs steps S301 to S303 by controlling each configuration of the substrate processing system 100.

Specifically, in step S301, the control device 90 calculates the distance WD between the centers of the substrates W1 and W2 held by the pair of end effectors 251R and 251L. In other words, the distance WD between the centers of the substrates W1 and W2 respectively held by the end effectors 251R and 251L of the vacuum transfer apparatus 25A is calculated based on the taught positions of the atmospheric transfer apparatus 55 obtained through the above-described steps S100 and S200.

As an example, it is assumed that the X coordinate of the taught position of the mounting platform 411 is −294.438 mm and the Y coordinate is 711.327 mm, and the X coordinate of the taught position of the mounting platform 412 is 298.113 mm and the Y coordinate is 709.133 mm. In this case, the center-to-center distance in the X-axis direction is 592.551 mm, which is obtained by subtracting −294.438 mm from 298.113 mm. In this case, the center-to-center distance in the Y-axis direction is −2.214 mm, which is obtained by subtracting 711.327 mm from 709.133 mm. As described above, the center-to-center distance WD between the substrates W1 and W2 based on the taught positions of the mounting platforms 411 and 412 differs from the design value, and a positional deviation may occur.

In other words, the taught positions of the mounting platforms 411 and 412 are positions adjusted so as to coincide with the center of each of the end effectors 251R and 251L in the above-described steps S100 and S200. FIG. 12A illustrates a state in which the center W1o of the substrate W1 is held in alignment with the center 251Ro of the end effector 251R, and the center W2o of the substrate W2 is held in alignment with the center 251Lo of the end effector 251L. Even when the centers are aligned as described above, the center-to-center distance WD between the substrates W1 and W2 may differ from the design value due to an assembly error of the vacuum transfer apparatus 25A, a processing error, an assembly error, or other similar factors.

To address such cases, in step S302, the control device 90 calculates a difference between the calculated center-to-center distance WD between the substrates W1 and W2 and the design value of the center-to-center distance. For example, if the center-to-center distance calculated in the X-axis direction is 592.551 mm and the center-to-center distance of the design value is 594 mm, the deviation amount is −1.449 mm, which is obtained by subtracting 594 mm from 592.551 mm. If the center-to-center distance calculated in the Y-axis direction is −2.214 mm and the center-to-center distance of the design value is 0 mm, the deviation amount is −2.214 mm.

In step S303, the control device 90 changes the substrate transfer positions of the mounting platforms 411 and 412 so that the centers W1o and W2o of the pair of substrates W1 and W2 and the centers 251Ro and 251Lo of the pair of end effectors 251R and 251L are shifted relatively equally. More specifically, when the vacuum transfer apparatus 25A simultaneously transfers the substrates W1 and W2 by the pair of end effectors 251R and 251L, the deviation amount calculated in step S302 is divided into two equal parts to calculate the respective adjustment amounts in the X-axis direction and the Y-axis direction. In the above example, the adjustment amount in the X-axis direction is −0.725 mm, which is obtained by dividing −1.449 mm by 2, and the adjustment amount in the Y-axis direction is −1.107 mm, which is obtained by dividing −2.214 mm by 2.

Thus, by changing the taught positions of the mounting platforms 411 and 412 in the atmospheric transfer apparatus 55, it is possible to hold the substrates by the end effectors 251R and 251L with the center-to-center distance according to the design value. In the above example, the X coordinate of the taught position of the mounting platform 411 is −294.438 mm, and the Y coordinate is 711.327 mm. Therefore, in the mounting platform 411, the adjusted X coordinate is −295.163 mm, which is obtained by adding −0.725 mm to −294.438 mm, and the adjusted Y coordinate is 710.220 mm, which is obtained by adding −1.107 mm to 711.327 mm. The X coordinate of the taught position of the mounting platform 412 is 298.113 mm, and the Y coordinate is 709.133 mm. Therefore, the adjusted X coordinate of the mounting platform 412 is 298.838 mm, which is obtained by subtracting −0.725 mm from 298.113 mm, and the adjusted Y coordinate is 710.220 mm, which is obtained by subtracting −1.107 mm from 709.133 mm.

By adjusting the taught position of the atmospheric transfer apparatus 55 in this way, the end effectors 251R and 251L of the vacuum transfer apparatus 25A respectively hold the substrates W1 and W2 that are displaced from the mounting platforms 411 and 412 in advance based on the design value. In other words, as illustrated in FIG. 12B, the center W1o of the substrate W1 is displaced and held relative to the center 251Ro of the end effector 251R, and the center W2o of the substrate W2 is displaced and held relative to the center 251Lo of the end effector 251L. However, the center-to-center distance WD between the substrates W1 and W2 is equal to the design value of the center-to-center distance.

The design value of the center-to-center distance between the substrates W1 and W2 can be set automatically (or by user input) based on the installation position of each stage of the processing modules 11 through 15 in advance. Alternatively, the design value of the center-to-center distance may be obtained by measuring the center-to-center distance of each installed stage and calculating an average value of each of the processing modules 11 through 15. The design value of the center-to-center distance may be different for each of the processing modules 11 through 15. In this case, the substrate processing system 100 may recognize the transfer to a target module among the processing modules 11 through 15 and change the substrate transfer positions of the mounting platforms 411 and 412 of the atmospheric transfer apparatus 55 for each of the processing modules 11 through 15.

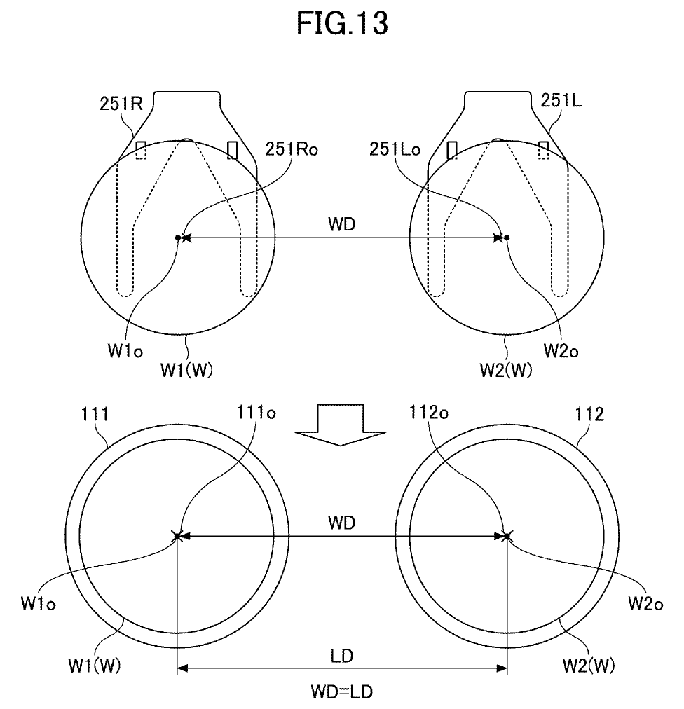

FIG. 13 is a diagram illustrating a state in which the position-adjusted substrates W1 and W2 are transferred to the stages 111 and 112 of the processing module 11. The design value of the center-to-center distance WD between the substrates W1 and W2 coincides with the center-to-center distance LD between the center 111o of the stage 111 and the center 112o of the stage 112 of the processing module 11, for example, as illustrated in FIG. 13. Therefore, when the end effectors 251R and 251L are transferred to the processing module 11, the vacuum transfer apparatus 25A can align the center-to-center distance WD between the held substrates W1 and W2 with the center-to-center distance LD between the stages 111 and 112.

As a result, when the end effectors 251R and 251L place the substrates W1 and W2 on the stages 111 and 112, the center Wo1 of the substrate W1 can be aligned with the center 111o of the stage 111, and the center W2o of the substrate W2 can be aligned with the center 112o of the stage 112. In other words, the substrates W can be placed on the stages 111 and 112 while suppressing the positional shift (for example, by securing the clearance of the edge protrusions). Thus, the processing module 11 can accurately process the substrates W1 and W2. In addition, when the stages 111 and 112 are movable, the deviation in the movable range of the stages 111 and 112 can be eliminated, so that the substrates W can be placed at an appropriate position during substrate processing.

The substrate processing system 100 and the teaching method of the present disclosure are not limited to the above embodiment, and various modifications may be adopted. For example, the vacuum transfer apparatuses 25A and 25B are not limited to a configuration for transferring two substrates W simultaneously, but may be configured to transfer three or more substrates W simultaneously by providing three or more end effectors. Even in this case, the vacuum transfer apparatuses 25A and 25B can accurately transfer three or more substrates W to target positions by adjusting the respective substrate transfer positions in the above teaching method.

### Notes

The technical concepts and effects of the present disclosure explained in the above embodiments will be described below.

A first aspect of the present disclosure is a substrate processing system 100 including: a transfer module (vacuum transfer module 20A); a first transfer apparatus (vacuum transfer apparatus 25A) installed in the transfer module and having a plurality of end effectors 251R and 251L configured to respectively hold a plurality of substrates W, the first transfer apparatus being configured to simultaneously transfer the plurality of substrates W; and a control device 90 configured to control an operation of the first transfer apparatus. The control device 90 controls (A) calculating a center-to-center distance WD between the plurality of substrates W when the plurality of substrates W are respectively held by the plurality of end effectors 251R and 251L; and (B) adjusting a position when the plurality of substrates are held by the plurality of end effectors 251R and 251L based on the center-to-center distance WD between the plurality of substrates calculated in the (A) and a design value of the center-to-center distance between the plurality of substrates W.

According to the above, the substrate processing system 100 adjusts the positions of the plurality of substrates W respectively held by the end effectors 251R and 251L based on the calculated center-to-center distance WD and the design value, so that the substrates W can be accurately moved to the respective target positions when the plurality of substrates W are simultaneously transferred. In other words, since the first transfer apparatus (vacuum transfer apparatus 25A) holds the substrates W based on the center-to-center distance of the design value, not on the centers of the end effectors 251R and 251L, the center-to-center distance of the design value can be maintained. Thus, the substrate processing system 100 can place the substrates W with this center-to-center distance even at the respective target positions, so that transfer can be performed while sufficiently suppressing a positional deviation of the substrates W from the target positions.

The substrate processing system 100 further includes: a plurality of mounting platforms 411 and 412 on which the plurality of substrates 1 are respectively placed by the plurality of end effectors 251R and 251L of the first transfer apparatus (vacuum transfer apparatus 25A); and a second transfer apparatus (atmospheric transfer apparatus 55) for transferring the plurality of substrates W to the plurality of mounting platforms 411 and 412. In the (B), the control device 90 adjusts substrate transfer positions when the second transfer apparatus places the plurality of substrates W on the plurality of mounting platforms 411 and 412 respectively. Thus, the substrate processing system 100 can transfer the substrates W to the adjusted substrate transfer positions when the substrates W are transferred by the atmospheric transfer apparatus 55, so that the vacuum transfer apparatus 25A can hold each substrate W as-is, and the transfer efficiency is enhanced.

In the (B), the control device 90 calculates a deviation amount between the center-to-center distance WD between the plurality of substrates W and the design value of the center-to-center distance between the plurality of substrates, and adjusts each of the substrate transfer positions of the plurality of mounting platforms 411 and 412 to a position where each of the plurality of substrates W are equally shifted based on the deviation amount. Thus, the substrate processing system 100 can hold the substrates W equally shifted by the end effectors 251R and 251L, and stably transfer the substrates W.

The substrate processing system 100 further includes a position detector 80 configured to detect the plurality of substrates W held by the plurality of end effectors 251R and 251L when the first transfer apparatus (vacuum transfer apparatus 25A) transfers the plurality of substrates W. Before performing the (A), the control device performs (C) recognizing a center of each of the plurality of end effectors 251R and 251L when the plurality of end effectors 251R and 251L hold the plurality of substrates W by causing the position detector 80 to perform detection. Thus, the substrate processing system 100 recognizes the centers of the end effectors 251R and 251L in advance, and can thereby appropriately recognize the center-to-center distance WD between the substrates W placed corresponding to the centers of the end effectors 251R and 251L.

In the (C), a process of recognizing an X-axis direction of the center of each of the plurality of end effectors 251R and 251L and a process of recognizing a Y-axis direction of the center of each of the plurality of end effectors 251R and 251L are separately performed. Thus, the substrate processing system 100 can accurately recognize the X coordinate and the Y coordinate of the centers of the end effectors 251R and 251L.

In the (C), the recognized center of each of the plurality of end effectors 251R and 251L is corrected using a correction amount of a positional deviation of the first transfer apparatus. Thus, the substrate processing system 100 can satisfactorily recognize the centers of the end effectors 251R and 251L including a processing error and an assembling error of the first transfer apparatus itself.

Before the (C), the control device 90 calculates the correction amount of the positional deviation of the first transfer apparatus (vacuum transfer apparatus 25A) by causing the position detector 80 to detect the plurality of end effectors 251R and 251L not respectively holding the plurality of substrates W. Thus, the substrate processing system 100 can accurately obtain a correction amount of a positional deviation of the first transfer apparatus.

The position detector 80 is an optical sensor capable of detecting an edge of a detection target object, and the plurality of end effectors 251R and 251L have through-holes 2514 which can be detected by the position detector 80. By utilizing the through-holes 2514 of the respective end effectors 251R and 251L, the substrate processing system 100 can easily obtain a correction amount a of a positional deviation of the first transfer apparatus (vacuum transfer apparatus 25A) by the position detector 80.

In the (D), an error of the position detector 80 is corrected based on a distance between inner edges of the detected through-holes 2514 and an actual size of the through-holes 2514. Thus, the substrate processing system 100 can easily obtain a correction amount a of a positional deviation of the first transfer apparatus, the centers of the end effectors 251R and 251L, and the like in consideration of errors of the position detector 80.

A second aspect of the present disclosure is a method of teaching a substrate processing system 100 comprising a transfer module (vacuum transfer module 20A) and a first transfer apparatus (vacuum transfer apparatus 25A) which is installed in the transfer module and having a plurality of end effectors 251R and 251L configured to respectively hold a plurality of substrates W, the plurality of end effectors 251R and 251L being configured to transfer the plurality of substrates W simultaneously. The teaching method includes (A) calculating a center-to-center distance between the plurality of substrates W when the plurality of substrates W are respectively held by the plurality of end effectors 251R and 251L; and (B) adjusting a position when the plurality of substrates W are held by the plurality of end effectors 251R and 251L based on the center-to-center distance between the plurality of substrates W calculated in the (A) and a design value of the center-to-center distance between the plurality of substrates W. In the teaching method according to this aspect, when a plurality of substrates W are simultaneously transferred, each substrate can be accurately moved to a target position.

The substrate processing system 100 and the teaching method according to the embodiments disclosed herein are exemplary and not restrictive in all respects. The embodiments can be modified and improved in various forms without departing from the scope and gist of the appended claims. The matters described in the above embodiments can be arranged in other configurations to the extent not inconsistent, and can be combined to the extent not inconsistent.

What is claimed is:

1. A substrate processing system comprising:
a transfer module;
a first transfer apparatus installed in the transfer module and having a plurality of end effectors configured to respectively hold a plurality of substrates, the first transfer apparatus being configured to simultaneously transfer the plurality of substrates; and
a control device including a processor and a memory coupled to the processor and storing a program for operating the substrate processing system, the processor configured to control each configuration of the substrate processing system by reading and executing the program from the memory, the control device configured to control an operation of the first transfer apparatus, wherein
the control device controls
(A) calculating a center-to-center distance between the plurality of substrates when the plurality of substrates are respectively held by the plurality of end effectors; and
(B) adjusting a position when the plurality of substrates are held by the plurality of end effectors based on the center-to-center distance between the plurality of substrates calculated in the (A) and a design value of the center-to-center distance between the plurality of substrates.

2. The substrate processing system according to claim 1, further comprising:
a plurality of mounting platforms on which the plurality of substrates are respectively placed by the plurality of end effectors of the first transfer apparatus; and
a second transfer apparatus for transferring the plurality of substrates to the plurality of mounting platforms, wherein
in the (B), the control device is further configured to adjust substrate transfer positions when the second transfer apparatus places the plurality of substrates on the plurality of mounting platforms respectively.

3. The substrate processing system according to claim 2, wherein
in the (B), the control device is further configured to
calculate a deviation amount between the center-to-center distance between the plurality of substrates and the design value of the center-to-center distance between the plurality of substrates; and
adjust each of the substrate transfer positions of the plurality of mounting platforms to a position where each of the plurality of substrates are equally shifted based on the deviation amount.

4. The substrate processing system according to claim 1, further comprising:
a position detector configured to detect the plurality of substrates held by the plurality of end effectors when the first transfer apparatus transfers the plurality of substrates, wherein
the control device is further configured to, before performing the (A), perform (C) recognizing a center of each of the plurality of end effectors when the plurality of end effectors hold the plurality of substrates, by causing the position detector to perform detection.

5. The substrate processing system according to claim 2, further comprising:
a position detector configured to detect the plurality of substrates held by the plurality of end effectors when the first transfer apparatus transfers the plurality of substrates, wherein
the control device is further configured to, before performing the (A), perform (C) recognizing a center of each of the plurality of end effectors when the plurality of end effectors hold the plurality of substrates by causing the position detector to perform detection.

6. The substrate processing system according to claim 3, further comprising:
a position detector configured to detect the plurality of substrates held by the plurality of end effectors when the first transfer apparatus transfers the plurality of substrates, wherein
the control device is further configured to, before performing the (A), perform (C) recognizing a center of each of the plurality of end effectors when the plurality of end effectors hold the plurality of substrates by causing the position detector to perform detection.

7. The substrate processing system according to claim 4, wherein
in the (C), a process of recognizing an X-axis direction of the center of each of the plurality of end effectors and a process of recognizing a Y-axis direction of the center of each of the plurality of end effectors are separately performed.

8. The substrate processing system according to claim 4, wherein
in the (C), the recognized center of each of the plurality of end effectors is corrected using a correction amount of a positional deviation of the first transfer apparatus.

9. The substrate processing system according to claim 6, wherein
the control device is further configured to, before performing the (C), calculate the correction amount of the positional deviation of the first transfer apparatus by causing the position detector to detect the plurality of end effectors not holding the plurality of substrates.

10. The substrate processing system according to claim 7, wherein
the position detector is an optical sensor capable of detecting an edge of a detection target object, and
the plurality of end effectors have through-holes which can be detected by the position detector.

11. The substrate processing system according to claim 8, wherein
in the (D), an error of the position detector is corrected based on a distance between inner edges of the detected through-holes and an actual size of the through-holes.

12. A method of teaching a substrate processing system comprising a transfer module and a first transfer apparatus that is installed in the transfer module and has a plurality of end effectors configured to respectively hold a plurality of substrates, the plurality of end effectors being configured to transfer the plurality of substrates simultaneously, the method of teaching comprising:
(A) calculating a center-to-center distance between the plurality of substrates when the plurality of substrates are respectively held by the plurality of end effectors; and
(B) adjusting a position when the plurality of substrates are held by the plurality of end effectors based on the center-to-center distance between the plurality of substrates calculated in the (A) and a design value of the center-to-center distance between the plurality of substrates.
